(19) United States
(12) Patent Application Publication
(10) Pub. No.: US 2011/0076482 A1
(43) Pub. Date: Mar. 31, 2011

(54) Metallized Barrier Material

(76) Inventors: Thomas R. Fields, Bellingham, MA (US); Kurt B. Gundlach, Warren, MA (US)

(21) Appl. No.: 12/883,168

(22) Filed: Sep. 15, 2010

Related U.S. Application Data
(63) Continuation-in-part of application No. 12/583,049, filed on Aug. 13, 2009.
(60) Provisional application No. 61/188,947, filed on Aug. 13, 2008.
(60) Provisional application No. 61/268,469, filed on Jun. 12, 2009.

(51) Int. Cl. B32B 3/26; C23C 16/06

(52) U.S. Cl. 428/319.1; 427/250

(57) ABSTRACT

A metallized barrier material comprising a base material, a first protective coating, a metallized layer, and a second protective coating. The base material has a first surface and a second surface. The base material is a dimensionally stable porous substrate. The first protective coating is applied to the first surface of the base material. The metallized layer is vapor deposited on the protective first surface of the base material to a desired optical density. The second protective coating applied to the metallized layer.

### CROSS REFERENCE TO RELATED APPLICATION

This application is a continuation in part of U.S. patent application Ser. No. 12/583,049 which was filed Aug. 13, 2009, entitled Metallized Barrier Material which claims priority from U.S. Provisional Patent App. Ser. No. 61/188,947 which was filed Aug. 13, 2008, entitled Metallized Barrier Film and Coating Therefor, and U.S. Provisional Patent App. Ser. No. 61/268,469 which was filed Jun. 12, 2009, entitled Metallized Barrier Film and Coating Therefor, the entire disclosure of each of which is incorporated herein by reference.

### BACKGROUND OF THE DISCLOSURE

1. Field of the Disclosure

The disclosure relates in general to protective films, substrates and covers, and more particularly, to a metallized barrier material having improved moisture barrier properties. Specifically, the metallized barrier material includes at least one coating that is applied to the underlying metallized substrate which precludes degradation of the underlying metallized layer and, in turn, the moisture barrier properties thereof. The metallized barrier material can then be utilized as a packaging material (alone or upon application thereof to another substrate material), or as a protective covering or wrap (where moisture barrier properties are significant).

2. Background Art

The use of various metal films and metal foils is well known in the art. In particular, such materials are often necessary in food grade application as barriers for moisture, or as moisture vapor barriers for applications such as concrete covers utilized during the curing of concrete.

For many food grade applications, aluminum foils are laminated or otherwise adhered to another substrate such as a cellulosic or a polymer base film or substrate. Problematically, the aluminum foil is rather expensive and relatively heavy. Additionally, aluminum foil when combined with substrates in packaging renders the package difficult to recycle, and compromises biodegradability.

It would be advantageous from both a cost and weight standpoint if the aluminum foils in such applications were replaced by biopolymer based films having metallized coatings, or metallized paperboard (i.e., cellulosic material). Such a construction would greatly facilitate biodegradability. Such a replacement is not without problems. In particular, the metallized coatings often fail (oxidize or are otherwise compromised), especially in high humidity applications. While coatings can be applied to the metallized layer, it has been difficult to formulate a coating which can adequately protect the metallized layer in such high humidity applications.

The foregoing is made even more difficult when utilizing such porous substrates, as biopolymers including PLA, PHA, thermoplastic starch and blends thereof, as well as cellulosic substrates. Such porous materials provide virtually no barrier properties, and as such, the metallized layer has no protection by virtue of the substrate.

For certain non-food applications, a metallized layer of aluminum (or other material) is deposited on a substrate, such as one of the foregoing biopolymers and/or paperboard substrates. Even in a short span of hours, the unprotected metal oxidizes thereby rendering the metallized layer largely ineffective. It would be advantageous if the oxidation of the metallized layer was retarded so that the effectiveness of the cover from the standpoint of moisture vapor transmission could be extended.

Thus, it is an object of the present invention to provide a coated metallized biopolymers including PLA, PHA, thermoplastic starch and blends thereof, or cellulosic substrates, that exhibits superior performance in high humidity applications for use in packaging and covering applications.

It is another object of the present invention to provide a coated metallized biopolymers including PLA, PHA, thermoplastic starch and blends thereof, or cellulosic substrate, that can replace laminated aluminum foil structures in many applications.

These objects as well as other objects of the present invention will become apparent in light of the present specification, claims, and drawings.

### SUMMARY OF THE DISCLOSURE

The invention is directed to a metallized barrier material. The metallized barrier material comprises a base material, a first protective coating, a metallized layer, and a second protective coating. The base material has a first surface and a second surface. The base material is a dimensionally stable porous substrate. The first protective coating is applied to the first surface of the base material. The metallized layer is vapor deposited on the protective first surface of the base material to a desired optical density. The second protective coating is applied to the metallized layer.

In a preferred embodiment, the base material comprises one of a cellulosic based material or a biopolymer.

In another preferred embodiment, a third protective coating is applied to the second surface of the base material.

Preferably, the base material is selected from the group consisting of: PLA, PHA, thermoplastic starches, blends thereof and cellulosic materials.

In another preferred embodiment, at least one of the first protective coating and second protective coating comprises one or more of the group consisting of: Dianal BR87, MB2998, MB7107, PB588, PB586, PB419, BR-57, TB-120, TB-121, Cork FP-3105, FP-2877, Cork FP-3122ND, Cork PC-93V, Dow DER 661 and Epon 1031.

In another preferred embodiment, the optical density of the metallized layer comprises 2.5 to 4.5.

Preferably, the MVTR in a tropical condition for 24 hours is less than 200 gsm.

In another aspect of the invention, the invention comprises a method of making a metallized barrier material comprising the steps of: providing a base material having a first surface and a second surface, the base material being a dimensionally stable porous substrate; applying a first protective coating in a solvent or water on the first surface of the base material; evaporating the solvent or water; vapor depositing a metallized layer on the first surface of the base material, to a desired optical density; applying a second protective coating in a solvent or water onto the metallized layer; and evaporating the solvent or water.

In a preferred embodiment, the method further comprises the step of applying a second protective coating to the first surface of the base material before vapor depositing the metallized layer.

In another preferred embodiment, the method comprises the steps of applying a third protective coating to the second surface of the base material.

### BRIEF DESCRIPTION OF THE DRAWINGS

The disclosure will now be described with reference to the drawings wherein:

FIG. 1 of the drawings is a cross-sectional view of a barrier film formed in accordance with the present invention; and

FIG. 2 of the drawings is a flow chart setting forth a method of manufacturing the present metallized barrier film.

### DETAILED DESCRIPTION OF THE DISCLOSURE

While this invention is susceptible of embodiment in many different forms, there is shown in the drawings and described herein in detail a specific embodiment with the understanding that the present disclosure is to be considered as an exemplification and is not intended to be limited to the embodiment illustrated.

It will be understood that like or analogous elements and/or components, referred to herein, may be identified throughout the drawings by like reference characters. In addition, it will be understood that the drawings are merely schematic representations of the invention, and some of the components may have been distorted from actual scale for purposes of pictorial clarity.

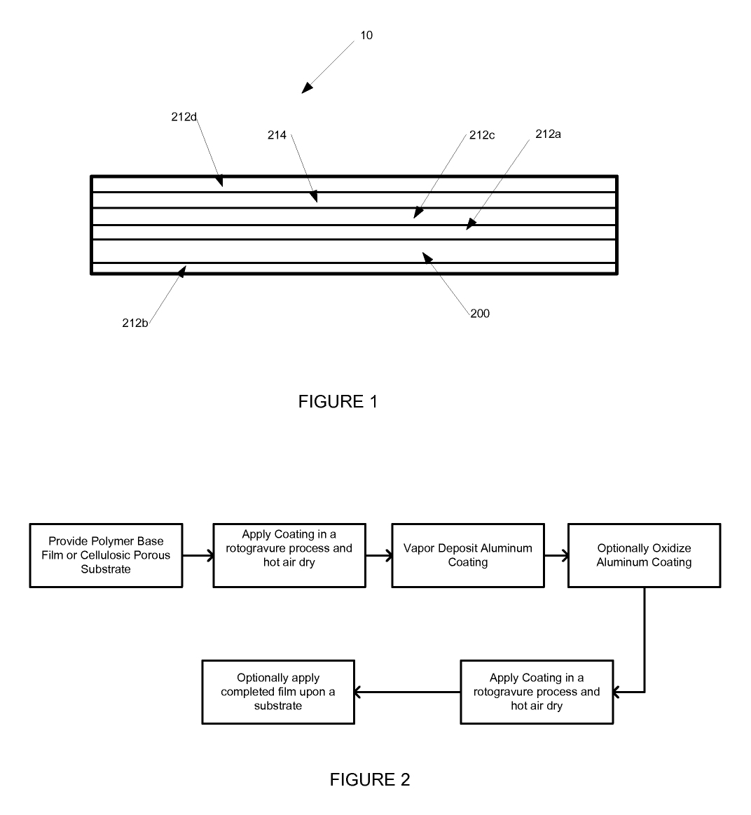

Referring now to the drawings and in particular to FIG. 1, a metallized barrier material is shown in FIG. 1 at 10. The metallized barrier material comprises a cellulosic or biopolymer substrate 200. The substrate (which may comprise a paperboard or other cellulosic material, or a biopolymer such as PLA, PHA and thermoplastic starches) may be coated with protective coating on both the top side 212a and the bottom side 212b. Prior to metallization of the top side of the substrate, a second coating is typically applied to the top surface 212c. The first coating tends to seal the top side of the substrate. The second coating provides a smooth surface upon which to deposit the aluminum through, for example, vapor deposition. It will be understood that in certain embodiments, the coatings 212a and 212b may be eliminated from the top or bottom side of the substrate, and, instead only the coatings on either side of the metallized layer, namely coatings 212c and 212d can be applied.

Once the coatings (optionally, 212b and 212c) have been applied, aluminum is vapor deposited on the coated substrate to form the metallized layer 214. Finally, another protective coating 212d is applied to the surface of the deposited aluminum. The resulting structure is shown in FIG. 1. The foregoing construction has advantages over aluminum foil which is typically used in applications wherein the above construction can be utilized.

The metallized barrier material can be utilized in association with packaging applications, wherein it can maintain the low initial barrier properties for extended periods of time even when exposed to high humidity atmospheric conditions. For example, the resulting barrier material can be used alone to form containers, bags, boxes or covers. In certain applications, it can be further coupled (adhered, laminated, etc) to an inner and/or outer surface of paper or boardstock or other substrate.

Typically, the polymer base film comprises a thickness of approximately 36 ga to 200 ga. For example, in other embodiments, the film substrates can be any number of different materials, namely, including, but not limited to, PLA, PHA, thermoplastic starch, and blends of these. It appears that the foregoing, bio-based polymeric films work well with the disclosed protective coating. It will be understood that the biopolymers, such as PLA, PHA and thermoplastic starches will tend to be substantially more porous to moisture.

With respect to utilizing cellulosic substrates, a paperboard can be utilized. It will be understood that with the porosity of most cellulosic substrates (as well as the biopolymers such as PLA, PHA and thermoplastic starches), it is advantageous to apply the protective coating described below to both sides of the metallized layer, and further, in certain embodiments to both sides of the cellulosic or biopolymer substrate. Such additional coatings further improve barrier qualities of the overall metallized barrier material.

Among other substrates, the following substrates have been contemplated for use: Sora Enso Uniset M having a basis weight of 68 gsm, New Page ProPoint having a basis weight of 56 gsm, Cham Tenero Adicar 2 having a basis weight of 80 gsm and Fraser Bladepak having a basis weight of 68 gsm. Of course, other substrates are contemplated for use, and these are provided for purposes of illustration (and for purposes of limitation).

The substrates that are contemplated for use typically comprise porous substrates. Regardless of its common definition, for purposes of the present disclosure, the term porous substrates mean a polymer or cellulosic substrates which overloads the sensors of a Mocon Permatran-W model 3-61 when tested at tropical conditions of 100° F., at 90%-100% relative humidity in less than four hours. Furthermore, the substrates that are contemplated for use in association with the present disclosure comprise dimensionally stable substrates. Regardless of its common definition, for purposes of the present disclosure, the term dimensionally unstable shall mean polymer or cellulosic substrates that change dimensions when exposed to a solvent (such as, for example, during a coating operation), heat (such as, for example, in a drying operation at 100-300° F.), or tension (more than 1 pli).

The metallized layer comprises a vapor deposited layer of aluminum upon the polymer base film or cellulosic substrate, which when exposed to air, partially oxidizes some of the aluminum into aluminum oxide. In many embodiments, the optical density of the deposited layer is approximately 2.5 to 3.5, while, a range of 1 to 4.5 is contemplated. It will be understood that other metals, including but not limited to tin and indium, among others, is likewise contemplated for use. It will be understood that an increase in the optical density decreases the moisture vapor transmission rate in a non-linear fashion. One graphical representation is shown on page 39 of the fourth edition of the Metallizing Technical Reference published by the Association of Industrial Metallizers Coaters and Laminators. Typically, the moisture vapor transmission rate of the metallized layer is compromised when the metal is oxidized by the moisture, and, in turn, loses its effectiveness.

To combat the oxidation of the metallized layer, protective coatings are provided. In the present disclosure, it has been found that a protective coating can provide the necessary protection for the metallized layer so as to preclude barrier reduction.

It will be understood that for application purposes, the protective coatings are in a solvent based formulation (or in a water based formulation). While other solvents are contemplated, the solvents may comprise ethyl acetate, methyl ethyl ketone, amongst others. Additionally, it will be understood that there may be relatively small amounts (i.e., less than approximately 10% by weight) of other ingredients, including, but not limited to surfactants, dyes, and/or anti-static agents.

The protective coatings comprise a number of different resins that are applied, essentially, to both sides of the metallized layer to protect the metallized layer from oxidizing on either side thereof. A number of different solvent based epoxies, acrylics and styrene-Acrylic (water based and solvent based) can be utilized, including, but not limited to Dianal BR87, MB2998, MB7107, PB588, PB586, PB419, BR-57, TB-120, TB-121 commercially available from Dianal America, Inc. of Pasadena, Tex., Cork FP-3105, FP-2877, Cork FP-3122ND, Cork PC-93V commercially available from Cork industries, Inc. of Folcroft, Pa., Dow DER 661 available from Dow Chemical Co., of Midland, Mich., Epon 1031 commercially available from Hexion Specialty Chemicals, Inc. of Columbus, Ohio, among others. The foregoing is for illustrative purposes and is not intended to be limiting.

A number of different exemplary embodiments were created and tested. The different embodiments were first prepared and then tested in tropical conditions of 100° F., at 90%-100% relative humidity for 24 hours. Preferably, the MVTR over such a test is under 200 gsm. Results for each example are set forth below.

### Example 1

A sample was prepared utilizing Stora Enso Uniset M as the substrate at a basis weight of 68 gsm. The substrate was coated on one side with Dianal BR-57 commercially available from Dianal America, Inc. of Pasadena, Tex. A metallized layer was applied thereto. Next, the metallized layer was coated with Dianal BR-57. After the 24 hour test, the moisture vapor transmission rate (MVTR) was measured as 18.85 gsm.

### Example 2

A sample was prepared utilizing Stora Enso Uniset M as the substrate at a basis weight of 68 gsm. The substrate was coated on one side with Dianal PB-588 commercially available from Dianal America, Inc. of Pasadena, Tex. A metallized layer was applied thereto. Next, the metallized layer was coated with Dianal PB-588. After the 24 hour test, the MVTR was measured at 48.00 gsm.

### Example 3

A sample was prepared utilizing Stora Enso Uniset M as the substrate at a basis weight of 68 gsm. The substrate was coated on one side with Dianal BR-57 commercially available from Dianal America, Inc. of Pasadena, Tex. A metallized layer was applied thereto. Next, the metallized layer was coated with Cork PC-93V commercially available from Cork Industries, Inc. of Folcroft, Pa. After the 24 hour test, the MVTR was measured at 58.45 gsm.

### Example 4

A sample was prepared utilizing New Page ProPoint as the substrate at a basis weight of 56 gsm. The substrate was coated on one side with Dianal MB-7301 commercially available from Dianal America, Inc. of Pasadena, Tex. mixed with Epon 1031 which is commercially available from Hexion Specialty Chemicals, Inc. of Columbus, Ohio. A metallized layer was applied thereto. Next, the metallized layer was coated with Dianal MB-7301 mixed with Epon 1031. After the 24 hour test, the MVTR was measured at 2.95 gsm.

### Example 5

A sample was prepared utilizing New Page DuraPoint as the substrate at a basis weight of 56 gsm. The substrate was coated with Dianal MB-7017 commercially available from Dianal America, Inc. of Pasadena, Tex. A metallized layer was applied thereto. Next, the metallized layer was coated with Dianal MB-7017. After the 24 hour test, the MVTR was measured at 3.41 gsm.

### Example 6

A sample was prepared utilizing Cham Tenero Adicar 2 as the substrate at a basis weight of 80 gsm. The substrate was coated with Dianal MB-7017 commercially available from Dianal America, Inc. of Pasadena, Tex. A metallized layer was applied thereto. Next, the metallized layer was coated with Dianal MB-7017. After the 24 hour test, the MVTR was measured at 2.02 gsm.

### Example 7

A sample was prepared utilizing Fraser Bladepak as the substrate at a basis weight of 68 gsm. The substrate was coated with INX AC 3345 commercially available from INX International Ink Co. of Kalamazoo, Mich. A metallized layer was applied thereto. Next, the metallized layer was coated with INX AC 3345. After the 24 hour test, the MVTR was measured at 115.00 gsm.

As can be seen from the results above, the coatings that were applied so as to coat either side of the metallized layer yielded satisfactory results despite the use of a porous substrate that without the coatings would not be suitable for use.

The foregoing description merely explains and illustrates the invention and the invention is not limited thereto except insofar as the appended claims are so limited, as those skilled in the art who have the disclosure before them will be able to make modifications without departing from the scope of the invention.

What is claimed is:

1. A metallized barrier material comprising:
a base material having a first surface and a second surface, the base material being a dimensionally stable porous substrate;
a first protective coating applied to the first surface of the base material;
a metallized layer vapor deposited on the protective first surface of the base material to a desired optical density;
a second protective coating applied to the metallized layer.

2. The metallized barrier material of claim 1 wherein the base material comprises one of a cellulosic based material or a biopolymer.

3. The metallized barrier material of claim 2 further comprising a third protective coating applied to the second surface of the base material.

4. The metallized barrier material of claim 2 wherein the base material is selected from the group consisting of: PLA, PHA, thermoplastic starches, blends thereof and cellulosic materials.

5. The metallized barrier material of claim 2 wherein at least one of the first protective coating and second protective coating comprises one or more of the group consisting of: Dianal BR87, MB2998, MB7107, PB588, PB586, PB419, BR-57, TB-120, TB-121, Cork FP-3105, FP-2877, Cork FP-3122ND, Cork PC-93V, Dow DER 661 and Epon 1031.

6. The metallized barrier material of claim 2 wherein the optical density of the metallized layer comprises 2.5 to 4.5.

7. The metallized barrier material of claim wherein the MVTR in a tropical condition for 24 hours is less than 200 gsm.

8. A method of making a metallized barrier material comprising the steps of:
providing a base material having a first surface and a second surface, the base material being a dimensionally stable porous substrate;
applying a first protective coating in a solvent or water on the first surface of the base material;
evaporating the solvent or water;
vapor depositing a metallized layer on the first surface of the base material, to a desired optical density;
applying a second protective coating in a solvent or water onto the metallized layer; and
evaporating the solvent or water.

9. The method of claim 8 further comprising the step of:
applying a second protective coating to the first surface of the base material before vapor depositing the metallized layer.

10. The method of claim 8 further comprising the step of applying a third protective coating to the second surface of the base material.
